(19) United States
(12) Patent Application Publication
(10) Pub. No.: US 2006/0160325 A1
(43) Pub. Date: Jul. 20, 2006

(54) Method of manufacturing semiconductor device

(76) Inventor: Chee-Hong Choi, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/312,387

(22) Filed: Dec. 21, 2005

(30) Foreign Application Priority Data
Dec. 22, 2004 (KR) 10-2004-0110219

(51) Int. Cl. H01L 21/76

(52) U.S. Cl. 438/424

(57) ABSTRACT

An exemplary method of manufacturing a semiconductor device according to an embodiment of the present invention includes forming an insulation layer on a silicon substrate; forming a shallow trench isolation (STI) pattern by a photolithography and etching process; forming a high density plasma (HDP) oxide layer on the STI pattern; forming a barrier layer on the HDP oxide layer; patterning the barrier layer by a photolithography and etching process; and planarizing the HDP oxide layer by CMP. The adoption of the barrier layer can prevent the occurrence of dishing, so pattern failures due to dishing can be suppressed.

### CROSS-REFERENCE TO RELATED APPLICATION

This application claims priority to and the benefit of Korean Patent Application No. 10-2004-0110219 filed in the Korean Intellectual Property Office on Dec. 22, 2004, the entire contents of which are incorporated herein by reference.

### BACKGROUND OF THE INVENTION

(a) Field of the Invention

The present invention relates to a method of manufacturing a semiconductor device. More particularly, the present invention relates to a method of suppressing a dishing phenomenon in a semiconductor device without using a dummy region.

(b) Description of the Related Art

As semiconductor devices have been highly integrated, planarization technologies for underlayers are required for acquiring a photo margin and minimizing the length of metal lines.

As examples, there are a first chemical mechanical polishing (CMP) process for planarizing a high density plasma (HDP) oxide layer in forming a shallow trench isolation (STI), a second CMP process for planarizing an interlayer insulation layer covering gate electrodes, a third CMP process for planarizing a polysilicon plug layer connected with the gate electrodes, a fourth CMP process for planarizing an interlayer insulation layer covering bit lines, and a fifth CMP process for planarizing an interlayer insulation layer covering capacitors.

The edge portion of a substrate has a lower pattern concentration than the center portion thereof, so the CMP may be over-performed. The CMP for planarizing an interlayer insulation layer covering capacitors may fail to planarize the center portion and the edge portion of a substrate with sufficient uniformity.

Accordingly, a dishing phenomenon wherein the surface of the substrate becomes concave may occur, so a pattern collapse or a pattern failure may happen in subsequent mask processes.

FIG. 1A to 1C are cross-sectional views showing principal stages of a semiconductor device according to a conventional method. As shown in FIG. 1A, an oxide layer 20, and a silicon nitride layer 30 are formed on a silicon substrate 10, and they are patterned by a photolithography and etching process so as to form shallow trench isolation (STI) region.

As shown in FIG. 1B and FIG. 1C, a high-density plasma (HDP) oxide layer 40 is deposited so as to fill the gap of the STI region, and is subsequently planarized by CMP. The silicon nitride layer 30 in an active region may prevent damage to the silicon substrate in the CMP process, and a narrow STI region may have little influence of dishing. However, if there is no dummy pattern, a wide STI region may suffer from a severe dishing phenomenon 50.

Therefore, during a subsequent process for forming copper lines on the upper layer, a short circuit due to copper residue may occur over the region where the dishing phenomenon occurs.

In such a conventional method, if there is no dummy pattern region, the dishing phenomenon may occur. However, the adoption of the dummy pattern region may cause capacitive coupling and a noise.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of manufacturing a semiconductor device having advantages of suppressing the occurrence of a dishing phenomenon without using a dummy pattern.

An exemplary method of manufacturing a semiconductor device according to an embodiment of the present invention includes forming an insulation layer on a silicon substrate; forming a shallow trench isolation (STI) pattern by a photolithography and etching process; forming a high density plasma (HDP) oxide layer on the STI pattern; forming a barrier layer on the HDP oxide layer; patterning the barrier layer by a photolithography and etching process; and planarizing the HDP oxide layer by CMP.

In a further embodiment, the barrier layer may be formed as a silicon nitride layer having a thickness of 500 Å-1500 Å.

In a further embodiment, after patterning the barrier layer, the barrier layer may be confined on a wide STI region.

In a further embodiment, the insulation layer may be formed by sequentially forming a silicon oxide layer and a silicon nitride layer.

Accordingly, the occurrence of capacitive coupling and the noise that is caused by adopting a dummy pattern can be prevented. That is, the adoption of the barrier layer can prevent the occurrence of dishing, so pattern failures due to dishing can be suppressed.

### BRIEF DESCRIPTION OF THE DRAWINGS

FIG. 1A to 1C are cross-sectional views showing principal stages of a semiconductor device according to a conventional method.

FIG. 2A to 2E are cross-sectional views showing principal stages of a semiconductor device according to an exemplary embodiment of the present invention.

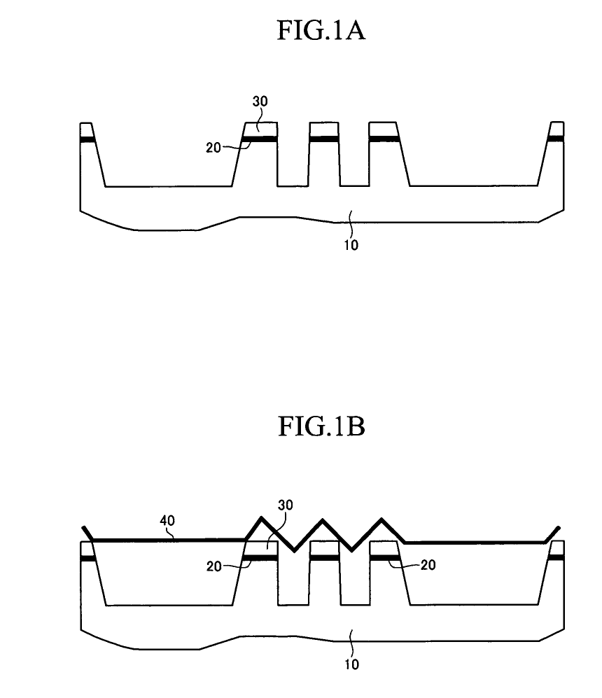

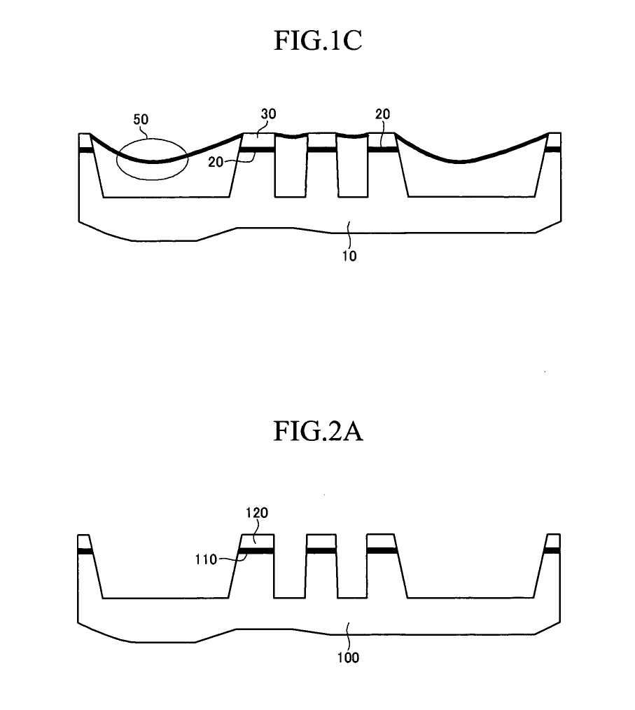

### DETAILED DESCRIPTION OF THE EMBODIMENTS

An exemplary embodiment of the present invention will hereinafter be described in detail with reference to the accompanying drawings.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

Now, an exemplary method of manufacturing a semiconductor device according to an embodiment of the present invention will be described in detail with reference to the accompanying drawings.

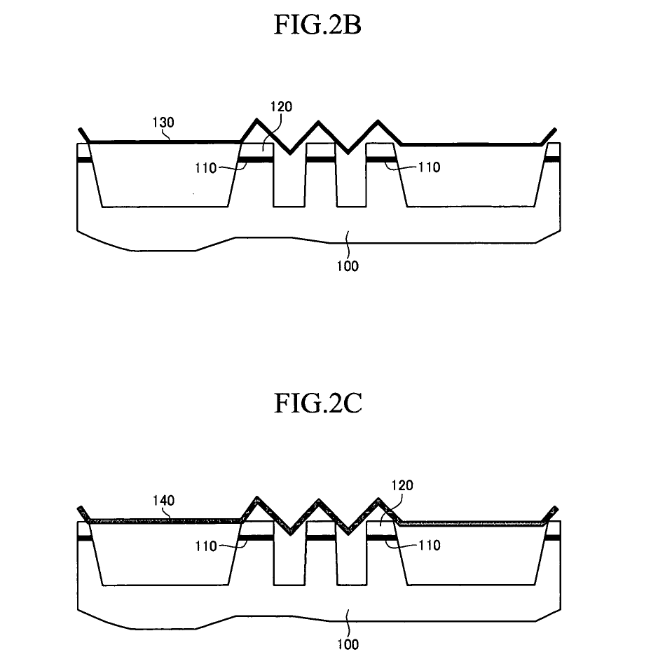

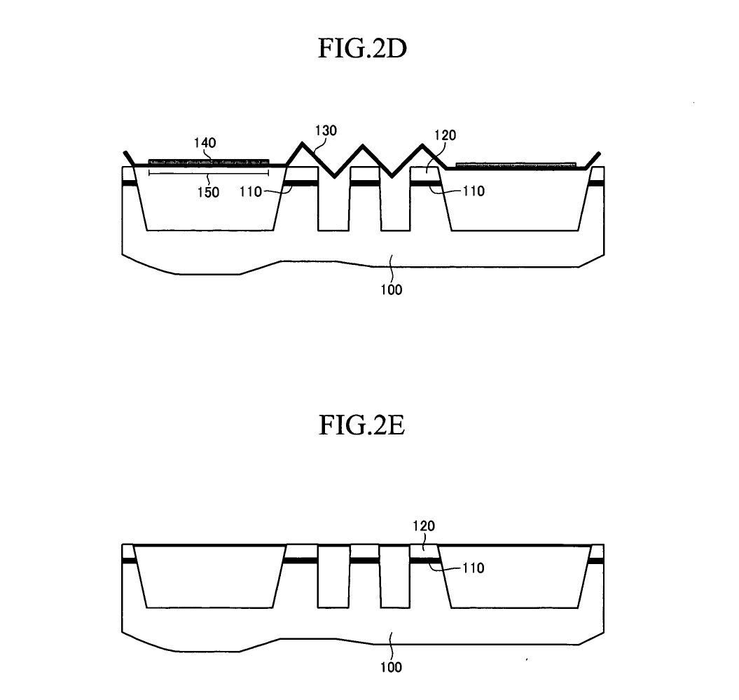

FIG. 2A to 2E are cross-sectional views showing principal stages of a semiconductor device according to an exemplary embodiment of the present invention. As shown in FIG. 2A, an oxide layer 110 and a silicon nitride layer 120 are sequentially formed on a silicon substrate 100, and they are patterned by a photolithography and etching process so as to form a shallow trench isolation (STI) region.

As shown in FIG. 2B and FIG. 2C, a high-density plasma (HDP) oxide layer 130 is deposited so as to fill the gap of the STI, and a barrier layer 140 is formed thereon so as to prevent dishing in a wide STI region. The barrier layer 140 may be formed to a thickness of 500 Å-1500 Å. In addition, the barrier layer 140 may be formed as a silicon nitride layer having high selectivity to HDP oxide layer 130.

As shown in FIG. 2D, the barrier layer 140 is patterned by a photolithography and etching process, so it is made to remain only in a wide STI region 150. The barrier layer 140 is used for preventing over-cutting of the HDP oxide layer 130 during a subsequent CMP process.

Subsequently, as shown in FIG. 2E, the HDP oxide layer 130 can be planarized by CMP without occurrence of dishing.

Therefore, the occurrence of capacitive coupling and the noise that is caused by adopting a dummy pattern can be prevented. That is, the adoption of the barrier layer can prevent the occurrence of dishing, so pattern failures due to dishing can be suppressed.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a semiconductor device, comprising:
forming an insulation layer on a silicon substrate;
forming a shallow trench isolation (STI) pattern by a photolithography and etching process;
forming a high density plasma (HDP) oxide layer on the STI pattern;
forming a barrier layer on the HDP oxide layer;
patterning the barrier layer by a photolithography and etching process; and
planarizing the HDP oxide layer by CMP.

2. The method of claim 1, wherein the barrier layer is formed to a thickness of 500 Å-1500 Å.

3. The method of claim 1, wherein the barrier layer is formed as a silicon nitride layer.

4. The method of claim 1, wherein the barrier layer is formed as a silicon nitride layer having a thickness of 500 Å-1500 Å.

5. The method of claim 1, wherein, after patterning the barrier layer, the barrier layer is confined on a wide STI region.

6. The method of claim 1, wherein the insulation layer is formed by sequentially forming a silicon oxide layer and a silicon nitride layer.
